(19) United States
(12) Patent Application Publication
(10) Pub. No.: US 2025/0191901 A1
(43) Pub. Date: Jun. 12, 2025

(54) MULTIFACETED TARGET FOR AN ION SOURCE

(71) Applicant: Axcelis Technologies, Inc., Beverly, MA (US)

(72) Inventor: Steve T. Drummond, Merrimac, MA (US)

(21) Appl. No.: 18/973,475

(22) Filed: Dec. 9, 2024

Related U.S. Application Data
(60) Provisional application No. 63/608,884, filed on Dec. 12, 2023.

(51) Int. Cl. H01J 37/34; H01J 37/08

(52) U.S. Cl. CPC H01J 37/3423; H01J 37/08; H01J 37/3417; H01J 37/3426; H01J 37/3491

(57) ABSTRACT

A target body includes a plurality of wave-shaped layers sandwiched between an upper target body and a lower target body. Adjacent layers of the plurality of wave-shaped layers are offset such that peaks of one layer interface with valleys of an adjoining layer, thereby forming a plurality of interstitial gas flow channels. The target body defines a central bore along a central axis of the target body that extends between opposite planar ends of the target body, and the plurality of interstitial gas flow channels are open to the central bore.

### CROSS-REFERENCE TO RELATED APPLICATIONS

This application claims priority to the provisional patent application filed Dec. 12, 2023, and assigned U.S. App. No. 63/608,884, the entire disclosure of which is hereby incorporated herein by reference.

### FIELD OF THE DISCLOSURE

This disclosure relates to ion implantation and, more specifically, to a target for an ion source.

### BACKGROUND OF THE DISCLOSURE

In the manufacture of semiconductor devices, ion implantation is used to dope semiconductors with impurities. Ion implantation systems are often used to implant a workpiece, such as a semiconductor wafer, with ions from an ion beam to produce n-type or p-type material doping or to form passivation layers during fabrication of an integrated circuit. Such beam treatment can selectively implant the wafers with impurities of a specified dopant material, at a predetermined energy level, and in controlled concentration to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material workpiece, whereas a “p-type” extrinsic material workpiece often results from ions generated with source materials such as boron, gallium, or indium.

A typical ion implanter includes an ion source, an ion extraction device, a mass analysis device, a beam transport device, and a process chamber. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, workpieces are transferred in to and out of the process chamber via a workpiece handling system, which may include one or more robotic arms, for placing a workpiece to be treated in front of the ion beam and removing treated workpieces from the ion implanter.

Ion sources (commonly referred to as arc ion sources) generate ion beams used in ion implanters and can include heated filament cathodes for creating ions that are shaped into an appropriate ion beam to treat a workpiece. For example, an ion source can have a cathode supported by a base and positioned with respect to a gas confinement chamber for ejecting ionizing electrons into the gas confinement chamber. The cathode can be a tubular conductive body having an endcap that partially extends into the gas confinement chamber. A filament can be supported within the tubular body and emits electrons that heat the endcap through electron bombardment, thereby thermionically emitting ionizing electrons into the gas confinement chamber.

A repeller is positioned opposite the cathode. A target can be provided near the repeller. The target is used as a source of ions, which are created by energetic sputtering of the target. Use of fluorine or other reactive species can enhance chemical etching of the material of the target.

### BRIEF SUMMARY OF THE DISCLOSURE

An embodiment of the present disclosure provides a target for an ion source. The target may comprise a target body comprising a plurality of wave-shaped layers sandwiched between an upper target body and a lower target body. Adjacent layers of the plurality of wave-shaped layers may be offset such that peaks of one layer interface with valleys of an adjoining layer, thereby forming a plurality of interstitial gas flow channels. The target body may define a central bore along a central axis of the target body that extends between opposite planar ends of the target body, and the plurality of interstitial gas flow channels may be open to the central bore.

In some embodiments, the target body may include a metal.

In some embodiments, the target body may comprise one or more of AlN or Al₂O₃.

In some embodiments, each of the plurality of wave-shaped layers may have at least two peaks and at least two valleys.

In some embodiments, the target body may further comprise a plurality of outer shielding layers. The plurality of outer shielding layers may be disposed between the upper target body and the lower target body and disposed radially outward from the plurality of wave-shaped layers.

In some embodiments, the plurality of outer shielding layers may have an aspect ratio (L/w) that is greater than 2:1.

In some embodiments, the target body may further comprise a plurality of inner shielding layers. The plurality of inner shielding layers may be disposed between the upper target body and the lower target body and disposed radially inward from the plurality of wave-shaped layers.

In some embodiments, the target body may further comprise an interface material.

The interface material may be disposed between each of the plurality of wave-shaped layers, and may join the peaks and the valleys of the adjacent layers together.

In some embodiments, the target may further comprise an arc chamber, a repeller, and an indirectly heated cathode. The target body may be disposed in the arc chamber. The repeller may be disposed through the central bore of the target body. The cathode may be disposed in the arc chamber opposite of the repeller.

In some embodiments, the target body may be formed by additive manufacturing.

In some embodiments, a thickness of each of the plurality of wave-shaped layers may be defined by multiple layers formed by additive manufacturing.

In some embodiments, the target body may be formed by brazing the plurality of wave-shaped layers together with the upper target body and the lower target body.

In some embodiments, a height of each of the plurality of wave-shaped layers may be less than a wavelength of each of the plurality of wave-shaped layers.

Another embodiment of the present disclosure provides a method. The method may comprise directing a stream of electrons and ions at a repeller and a target body that includes a metal. The target body may comprise a plurality of wave-shaped layers sandwiched between an upper target body and a lower target body, and adjacent layers of the plurality of wave-shaped layers may be offset such that peaks of one layer interface with valleys of an adjoining layer, thereby forming a plurality of interstitial gas flow channels. The target body may define a central bore along a central axis of the target body that the repeller is disposed within and the plurality of interstitial gas flow channels may be open to the central bore. The method may further comprise eroding metal ions from the target body using the stream of electrons and ions.

In some embodiments, the eroding may include physical sputtering and/or a chemical reaction.

In some embodiments, the method may further comprise feeding an etching gas through the plurality of interstitial gas flow channels. The etching gas may react with the target body and the stream of electrons and ions to cause the eroding.

Another embodiment of the present disclosure provides a method. The method may comprise forming a target body using additive manufacturing. The target body may comprise a plurality of wave-shaped layers sandwiched between an upper target body and a lower target body, and adjacent layers of the plurality of wave-shaped layers may be offset such that peaks of one layer interface with valleys of an adjoining layer, thereby forming a plurality of interstitial gas flow channels. The target body may define a central bore along a central axis of the target body that extends between opposite planar ends of the target body, and the plurality of interstitial gas flow channels may be open to the central bore.

In some embodiments, each of the plurality of wave-shaped layers may be defined by multiple layers formed by additive manufacturing.

### DESCRIPTION OF THE DRAWINGS

For a fuller understanding of the nature and objects of the disclosure, reference should be made to the following detailed description taken in conjunction with the accompanying drawings, in which:

FIG. 1 is a cross-sectional view of a target used in an ion source in accordance with an embodiment of the present disclosure;

FIG. 2 is a perspective view of an embodiment of a target in accordance with another embodiment of the present disclosure;

FIG. 3 is a perspective view of another embodiment of a target in accordance with another embodiment of the present disclosure;

FIG. 4A is a perspective view of another embodiment of a target in accordance with another embodiment of the present disclosure;

FIG. 4B is a side view of the target of FIG. 4A;

FIG. 5A is a perspective view of another embodiment of a target in accordance with another embodiment of the present disclosure;

FIG. 5B is a side view of the target of FIG. 5A;

FIG. 6 is a flowchart of a method in accordance with the present disclosure; and

FIG. 7 is a block diagram of an exemplary vacuum system utilizing an ion source with a target in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

In an ion implanter, a solid target is bombarded with electrons or with electrons and ions and, as a result, ions of the target material are ejected from the target. These ions can be directed toward a workpiece in the ion implanter. This ion bombardment of the target not only causes ions of the target materials to be ejected, but imparts considerable thermal energy to the target itself.

Ion source lifetime during operation is usually limited by erosion of the cathode instead of depletion of the target. The rate of removal of the material in the target is a function of the temperature of the target and the area of target material participating in the reaction. Cathode erosion rates can be determined by the arc currents and voltages used in the ion source. An improved target that has improved thermal characteristics and provides a larger reaction surface will enable target beam currents to be achieved with lower arc currents and voltages and, thereby, may reduce the cathode erosion rate.

Embodiments disclosed herein provide a target used for ion implantation that has improved thermal characteristics and presents a larger reaction area than those previously used. Targets used in sputter sources generally have a cylindrical, tubular, or slab-like shape. Inventor observation shows that reaction rates are higher when the target is in a location where it runs hotter (such as on the cathode-repeller axis). Restricting the cross-section area of the target near the base where it attaches to the ion source is typically advantageous because it restricts the conductive flow of heat out of the target and causes the plasma-facing face to become hotter, which increases the reaction rate. An increased reaction rate can provide improved beam current in an ion beam.

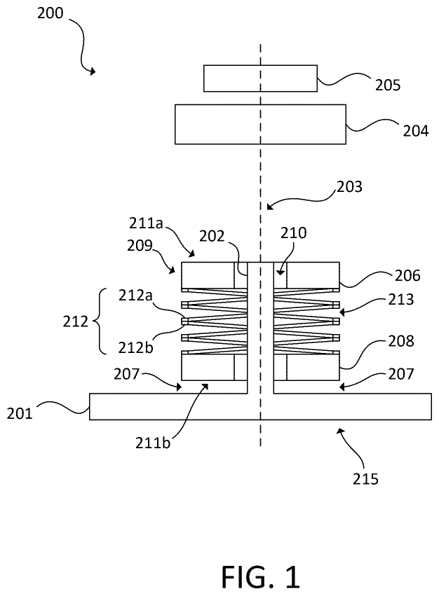

FIG. 1 is a cross-sectional view of a target used in an ion source 200. The components of the ion source 200 may be inside an arc chamber (not shown in FIG. 1). A source gas may be injected into the arc chamber during operation.

A filament 205 is heated by current supplied by a power supply (not shown), such that the filament 205 projects thermionic electrons toward the heated cathode 204, which in turn heats the cathode 204 and causes thermionic electrons to be emitted from the cathode 204. The thermionic electrons are projected from the heated cathode 204 along a central axis 203. A repeller 201 is positioned opposite the heated cathode 204 along the central axis 203. While illustrated in FIG. 1 as part of an indirectly-heated cathode, the ion source 200 also can use a thermally-heated filament without a cathode 204 or can use a radio frequency (RF) antenna.

The heated cathode 204 is heated to temperatures high enough for it to thermally emit electrons into the arc chamber, which is held at a potential that is positive with respect to the heated cathode 204 to accelerate the electrons. A magnetic field helps confine the electrons along field lines between the heated cathode 204 and repeller 201 to reduce the loss of electrons. The loss of electrons is further reduced by the repeller 201, which can be held at the potential of the heated cathode 204 to reflect electrons back toward the heated cathode 204. The excited electrons ionize material to generate a plasma (not shown). Ions are extracted through an aperture in the arc chamber (not shown) and electrostatically accelerated to form a high energy ion beam by an electrode positioned outside the arc chamber.

In operation, the heated cathode 204 (e.g., a cathode composed of tungsten or tantalum) is indirectly heated via the filament 205 and is used to start and sustain the ion source plasma (e.g., a thermionic electron emission). The heated cathode 204 and the repeller 201, for example, are at a negative potential in relation to other components of the arc chamber, and both the heated cathode 204 and repeller 201 can be eroded by the ionized gases.

A target 209 is positioned around a repeller shaft 202 of the repeller 201. The target 209 may comprise a target body that wraps around the repeller shaft 202 (i.e., both into and out of the page of FIG. 1). The target body may comprise a plurality of wave-shaped layers 212 sandwiched between an upper target body 206 and a lower target body 208. In an instance, the target 209 has a central bore 210 that is defined by the target body (i.e., extending through the upper target body 206, the plurality of wave-shaped layers 212, and the lower target body 208). The central bore 210 can be positioned along the central axis 203. The repeller shaft 202 can be positioned in the central bore 210. In an instance, the central bore 210 extends between the planar end 211a of the upper target body 206 and the planar end 211b of the lower target body 208. While illustrated as flush with the planar end 211a of the upper target body 206, the repeller shaft 202 can extend beyond the planar end 211a of the upper target body 206 or can be positioned entirely below an outer surface of the upper target body 206.

The target body can be fabricated of a metal-containing material. For example, the target body can include, consist of, or consist essentially of AlN or Al₂O₃. The target body also can include, consist of, or consist essentially of a gallium alloy (e.g., gallium nitride or gallium oxide). Other materials are possible, and these are merely examples. In an instance, the target body is not exclusively a metal. For example, the target body can include ceramics or polymer materials. In this case, the metal is a target ion and the target body can be, for example, an insulator. The components of the target body may be fabricated of the same or different materials. For example, the plurality of wave-shaped layers 212 may be the same or different materials from the upper target body 206 and the lower target body 208. The lower target body 208 may also be a different material from the upper target body 206. In an instance, the lower target body 208 may be a material configured to operate as a thermal sink and may not be a material that is a source of sputter material that would be used for the upper target body 206. In another instance, the target 209 may not include the lower target body 208.

Insulators can be used to isolate different parts of the target body with different voltages, e.g., parts bearing against the upper target body 206 and the lower target body 208. In a vacuum, heat transfer by convection may be minimal or non-existent, so the primary method of heat transfer may be by conduction between the upper target body 206 and the lower target body 208. The effectiveness and useful life of the insulator may depend on the length of the conductive path between the upper target body 206 and the lower target body 208, referred to as the “tracking length” herein. In the embodiments of the present disclosure, the arrangements of the plurality of wave-shaped layers 212 may increase the tracking length.

In an instance, the target body is substantially cylindrical. For example, the upper target body 206 and the lower target body 208 may be ring-shaped structures having similar diameters, and the plurality of wave-shaped layers 212 may also be ring-shaped and have diameters that are less than or equal to the diameters of the upper target body 206 and the lower target body 208. However, the target body also can be polygonal or other shapes.

Adjacent layers of the plurality of wave-shaped layers 212 may be offset from one another. In other words, the adjacent layers of the plurality of wave-shaped layers 212 may be at different rotational positions from each other relative to the central axis 203. Each of the plurality of wave-shaped layers 212 may have continuous wave-shaped profile defined by valleys 212a (i.e., the lowest points of the wave-shaped profile) and peaks 212b (i.e., the highest points of the wave-shaped profile). In some embodiments, each of the plurality of wave-shaped layers 212 may have at least two valleys 212a and at least two peaks 212b. Based on the offset of the adjacent layers, the peaks 212b of a lower layer may interface with the valleys 212a of the adjacent layer above. The valleys 212a of the lower-most wave-shaped layer 212 may be disposed on the lower target body 208, and the peaks 212b of the upper-most wave-shaped layer 212 may be disposed on the upper target body 206. Accordingly, the plurality of wave-shaped layers 212 may be stacked (e.g., not nested) along the central axis 203 between the upper target body 206 and the lower target body 208. Based on the profile of the plurality of wave-shaped layers 212, the valleys 212a and the peaks 212b may interface at a point, line, edge, face, or surface of adjacent layers.

The structural strength of the target 209 (e.g., axial, moment, and torsional loads) may depend on the number of waves of each of the plurality of wave-shaped layers 212. For example, a larger number of waves may increase the structural strength.

A gas flow channel 207 can enable gas flow between the lower target body 208 and a base 215 of the repeller 201. The gas flow channel 207 also can enable gas flow between the lower target body 208 and the repeller shaft 202. For example, a gas that includes fluorine (e.g., BF₃ or PF₃) can be used with the gas flow channel 207. Such a gas may be an ion source gas or an etchant gas which can improve the reaction rate and/or the erosion of the target material.

Based on the offset arrangement of the plurality of wave-shaped layers 212, a plurality of interstitial gas flow channels 213 may be formed between adjacent layers. For example, each of the plurality of interstitial gas flow channels 213 may be defined by the space between the valleys 212a of one layer and the peaks 212b of the adjacent layer above. The plurality of interstitial gas flow channels 213 may be open to the central bore 210. Accordingly, the plurality of interstitial gas flow channels 213 can enable gas flow along the length of the repeller shaft 202 within the target body.

In an instance, an etching gas is fed into the arc chamber with the target 209 through a passage through the target and support structure, such as the gas flow channel 207 and the plurality of interstitial gas flow channels 213, which enables a reaction. In an instance, the chemical reaction is between the etchant gas and material in the target 209 assisted by the energy of ions and electrons from the plasma. The primary electrons emitted from the cathode 204 may tend to have less of an effect in this process than positive ions from the plasma because the positive ions have both higher mass.

During operation, electrons are projected from the heated cathode 204 and generate a plasma. Material from the target 209 can be eroded from the upper target body 206 by the electrons and ions from the plasma. In an instance, the target 209 may not include the upper target body 206, and material can be eroded directly from the plurality of wave-shaped layers 212. The term “erode” herein can include physical and/or chemical aspect.

Embodiments disclosed herein can improve thermal characteristics of the target 209. In an instance, the plurality of wave-shaped layers 212 increase the tracking length for conductive heat transfer from the upper target body 206 to the lower target body 208. A lower conductance may affect the temperature of the target 209, which may increase the reaction rate and/or other erosion.

Embodiments disclosed herein can also provide a more tortuous path for any gas flow through the target 209. In an instance, the plurality of interstitial gas flow channels 213 provide an open structure for improved transmission of etchant gases through the target 209, which can increase the reaction rate and/or other erosion. The gases can also be more easily pumped out, which can reduce coating on the target 209.

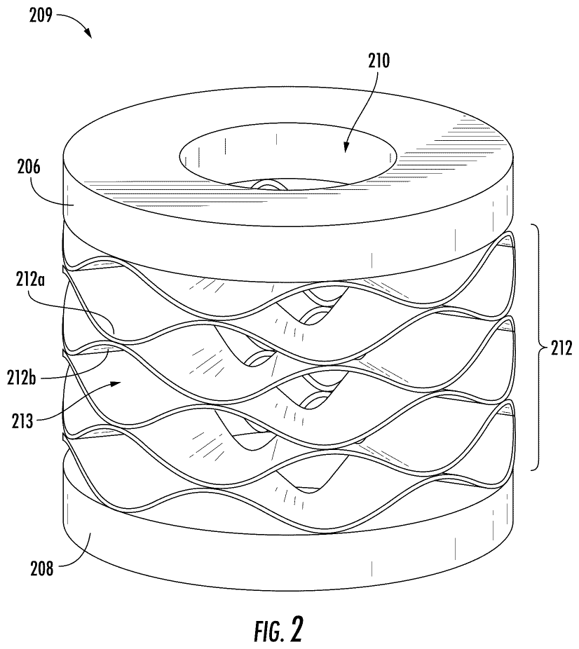

FIG. 2 is a perspective view of an embodiment of a target 209. In this embodiment, the plurality of wave-shaped layers 212 include 6 layers that are rotationally offset from each other. In other words, the plurality of wave-shaped layers 212 may have a sinusoidal shape, where adjacent layers are about 180 degrees out of phase with one another. Although the plurality of wave-shaped layers 212 are shown having symmetrically curved profile, the plurality of wave-shaped layers 212 may have a profile that is asymmetrical, jagged, square, flat, angled, arc-shaped, diagonal, or other profiles and is not limited herein. The plurality of interstitial gas flow channels 213 can improve transmission of gases through the target 209. As can be seen, a height of each of the plurality of wave-shaped layers 212 may be less than a wavelength of each of the plurality of wave-shaped layers 212. This structure may provide a shape that is capable of taking on different forms of loads (e.g., axial, moment, and torsional loads) and may allow the target 209 to be used in different orientations.

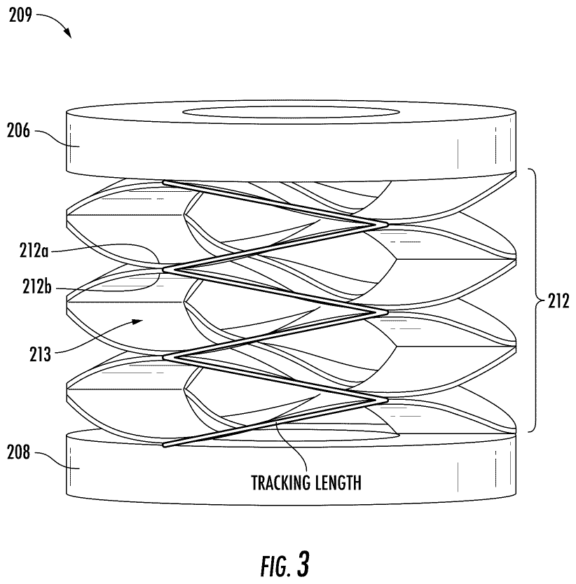

FIG. 3 is a perspective view of another embodiment of a target 209. This embodiment differs from FIG. 2 in that the plurality of wave-shaped layers 212 have a longer wavelength (i.e., a fewer number of waves). In other words, the plurality of wave-shaped layers 212 have fewer valleys 212a and peaks 212b. Accordingly, there may be fewer interstitial gas flow channels 213 that are larger in size, which can improve gas transmission. FIG. 3 also shows the tracking length between the upper target body 206 and the lower target body 208 provided by the plurality of wave-shaped layers 212. As can be seen, the tracking length provided by the plurality of wave-shaped layers 212 provides a tortuous path for conductive heat transfer, which can improve the insulating properties of the target 209. The tracking length may depend on the number of waves in each of the plurality of wave-shaped layers 212. As the adjacent layers of the plurality of wave-shaped layers 212 only interface as small areas, conduction can be isolated along the tracking length.

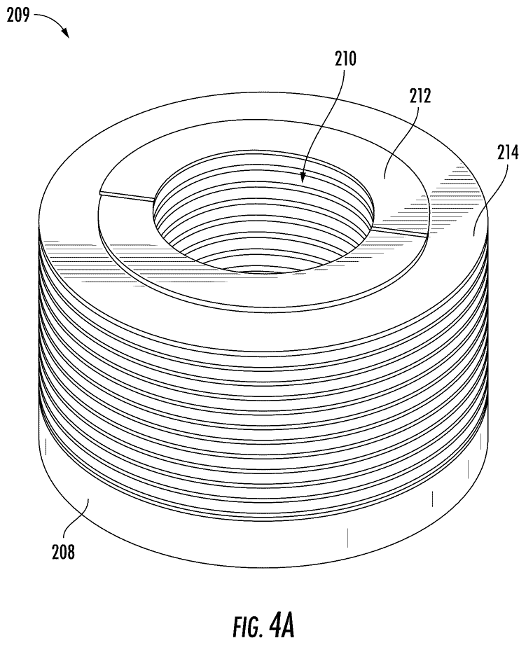

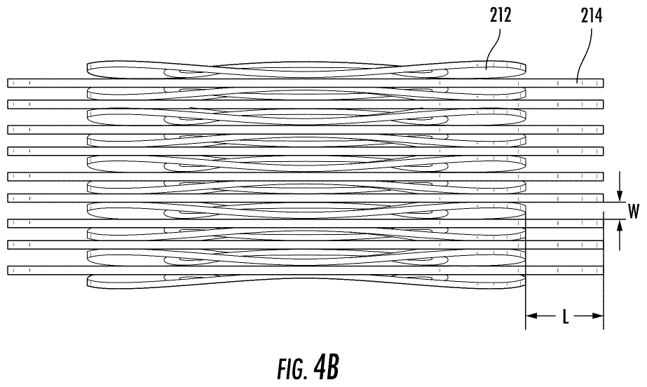

FIG. 4A is a perspective view of another embodiment of a target 209. In this embodiment, the target 209 further comprises a plurality of outer shielding layers 214. The plurality of outer shielding layers 214 may be disposed between the upper target body 206 and the lower target body 208 and may be disposed radially outward from the plurality of wave-shaped layers 212. For ease of illustration, the upper target body 206 is omitted from FIG. 4A, but it should be understood that the upper target body 206 is disposed on top of the plurality of wave-shaped layers 212, similar to the other embodiments described herein. The plurality of outer shielding layers 214 may be ring-shaped and may be supported by the plurality of wave-shaped layers 212. For example, the plurality of outer shielding layers 214 may be connected to the plurality of wave-shaped layers at the interfaces between adjacent layers (i.e., where the peaks 212b of a lower layer interface with the valleys 212a of the adjacent layer above). The plurality of outer shielding layers 214 may prevent premature coating of the plurality of wave-shaped layers 212. As shown in FIG. 4B, the plurality of outer shielding layers 214 may have an aspect ratio (L/w) that is greater than 2:1. Further increasing the aspect ratio may increase the life of the target 209, but smaller aspect ratios can also be used. The aspect ratio selected may depend on available space. The plurality of outer shielding layers 214 may be the same or different materials from the plurality of wave-shaped layers 212.

Similarly to the plurality of outer shielding layers 214, the target 209 may further comprise a plurality of inner shielding layers (not shown) that may be disposed between the upper target body 206 and the lower target body 208 and may be disposed radially inward from the plurality of wave-shaped layers 212. The plurality of inner shielding layers may further prevent premature coating of the plurality of wave-shaped layers.

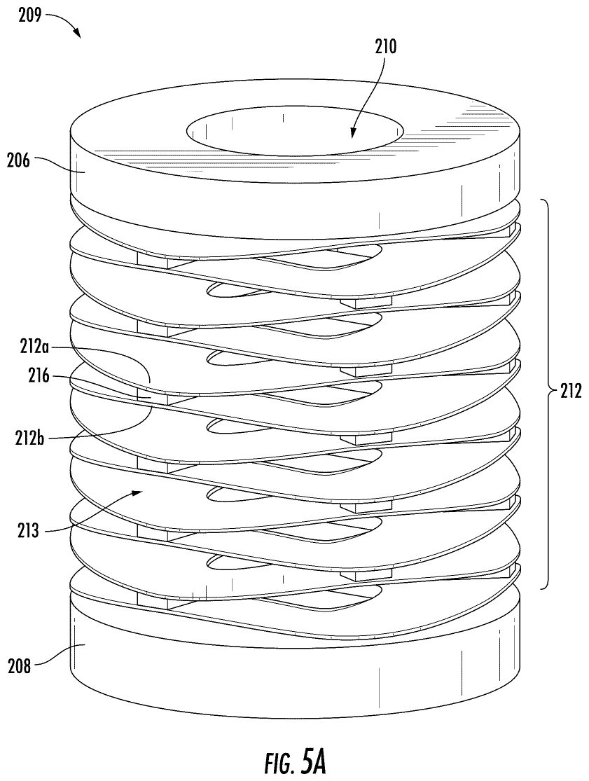

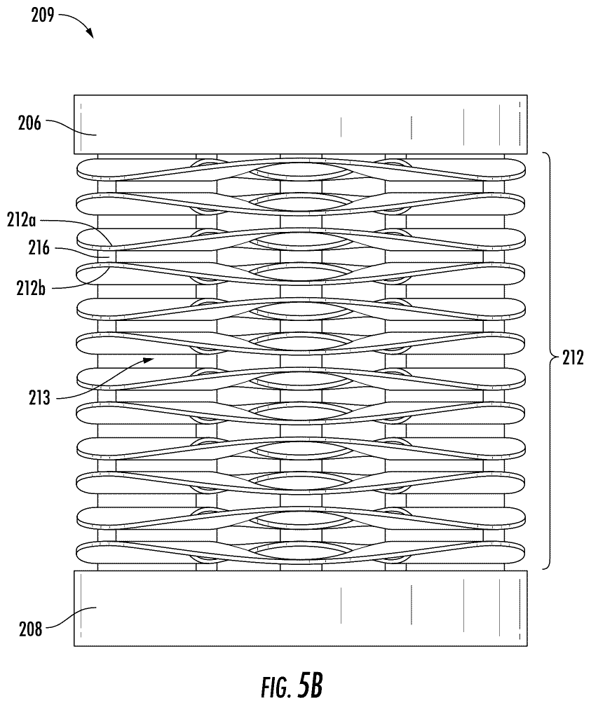

FIG. 5A is a side view of another embodiment of a target 209. In this embodiment, the plurality of wave-shaped layers include 12 layers that are rotationally offset from each other. The target 209 further includes an interface material 216 disposed between each of the plurality of wave-shaped layers 212. For example, the interface material 216 may be used to join the peaks 212b and the valleys 212a of the adjacent layers together. The interface material 216 may be comprised of the same or a different material from the plurality of wave-shaped layers 212. The interface material 216 may be configured to control the thermal conductivity between adjacent layers of the plurality of wave-shaped layers. As shown in FIG. 5B, the interface material 216 may extend radially from an outer edge to an inner edge each wave-shaped layer 212.

The various embodiments of FIGS. 2-5 can be combined or used separately.

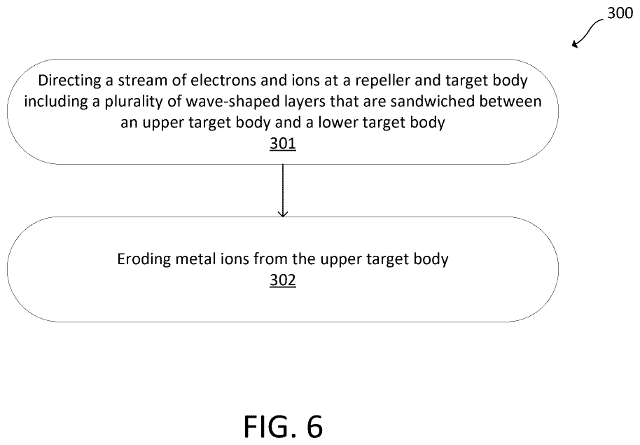

FIG. 6 is a flowchart of a method 300, which can use any of the embodiments disclosed herein. At 301, a stream of electrons and ions is directed at a repeller 201 and a target body that includes a metal, such as AlN or Al₂O₃. The target body includes a plurality of wave-shaped layers 212 that are sandwiched between an upper target body 206 and a lower target body 208, where adjacent layers are offset such that the peaks 212b of a lower layer interface with the valleys 212a of an adjoining layer above, thereby forming a plurality of interstitial gas flow channels 213 that are open to the central bore 210. Metal ions are eroded from the target body using the stream of electrons and ions at 302. These metal ions can then be used in ion implant application. The eroding can include physical sputtering and/or a chemical reaction. An etching gas can be fed through the plurality of interstitial gas flow channels 213 to further react with the metal of the target body and the stream of electrons and ions to cause the eroding.

The geometry of the embodiments of FIGS. 2-5 can be configured to provide desired thermal characteristics. Since the etchant rate is dependent on temperature, increasing the temperature profile can be beneficial. Increasing temperature profile toward a center of the arc chamber for a given input and output boundary condition can provide improved performance. The temperature profile can be linear or non-linear. For example, the temperature profile may be logarithmic with only a small cold section in the target 209.

In an instance, a reaction and/or other erosion occurs at the front of the target 209, such as the planar end 211a of the upper target body 206 in FIG. 1. Conductive heat transfer may occur out the opposite side of the target 209, such as the planar end 211b of the lower target body 208 by the gas flow channel 207 in FIG. 1. The heat transfer profile may not be uniform from the front to the back of the target 209. For example, there may be a temperature gradient along the target 209, along the tracking length defined by the plurality of wave-shaped layers 212.

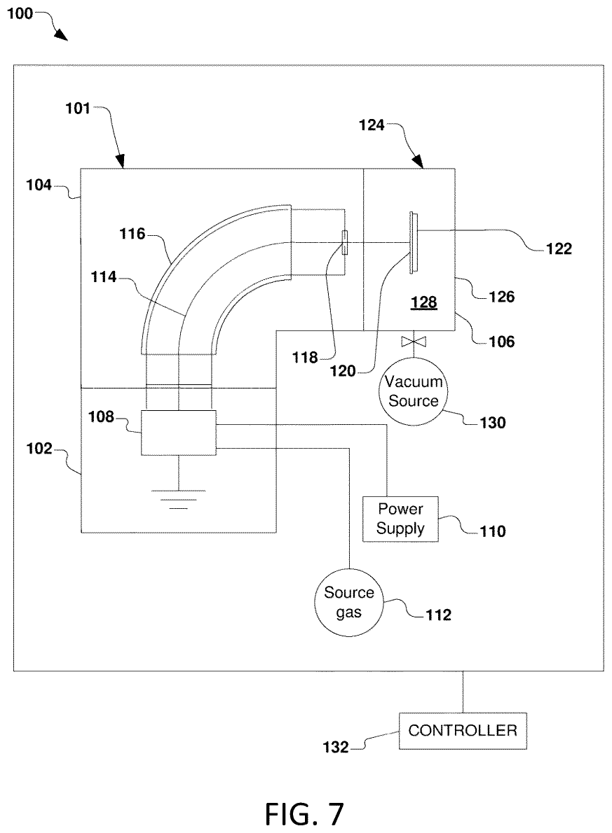

FIG. 7 illustrates an exemplified vacuum system 100 that may implement various apparatus, systems, and methods of the present disclosure. The vacuum system 100 includes an ion implantation system 101, however various other types of vacuum systems are also contemplated, such as plasma processing systems or other semiconductor processing systems. The ion implantation system 101, for example, comprises a terminal 102, a beamline assembly 104, and an end station 106.

Generally speaking, an ion source 108 in the terminal 102 is coupled to a power supply 110, whereby a gas from a gas source 112 (also called a dopant gas) supplied thereto and/or material from a target (such as that in FIG. 1) is ionized into a plurality of ions to form an ion beam 114. The ion beam 114 is directed through a beam-steering apparatus 116 and out an aperture 118 toward the end station 106. In the end station 106, the ion beam 114 bombards a workpiece 120 (e.g., a semiconductor such as a silicon wafer, a display panel, etc.), which is selectively clamped or mounted to a chuck 122 (e.g., an electrostatic chuck). Once embedded into the lattice of the workpiece 120, the implanted ions change the physical and/or chemical properties of the workpiece 120. Because of this, ion implantation is used in semiconductor device fabrication and in metal finishing, as well as various applications in materials science research.

The ion beam 114 of the present disclosure can take any form, such as a pencil or spot beam, a ribbon beam, a scanned beam, or any other form in which ions are directed toward end station 106, and all such forms are contemplated as falling within the scope of the disclosure.

The end station 106 includes a process chamber 124, such as a vacuum chamber 126, wherein a process environment 128 is associated with the process chamber. The process environment 128 within the process chamber 124, for example, comprises a vacuum produced by a vacuum source 130 (e.g., a vacuum pump) coupled to the process chamber 124 and configured to substantially evacuate the process chamber 124. A controller 132 is provided for overall control of the vacuum system 100.

The embodiments of the present disclosure may be implemented in various semiconductor processing equipment such as chemical vapor deposition (CVD), physical vapor deposition (PVD), metal organic chemical vapor deposition (MOCVD), etching equipment, and various other semiconductor processing equipment, and all such implementations are contemplated as falling within the scope of the present disclosure. The embodiments of the present disclosure further advantageously improve the performance of the ion source 108 and increase overall productivity and lifetime of the vacuum system 100.

The ion source 108 (also called an ion source chamber), for example, can be constructed using refractory metals (W, Mo, Ta, etc.) and graphite in order to provide suitable high temperature performance, whereby such materials are generally accepted by semiconductor manufacturers. The gas from the gas source 112 is used within the ion source 108. The gas may or may not be conductive in nature. However, after the gas is cracked or fragmented, the ionized gas can aid in chemical etching of a target material used for implantation, such as AlN or Al₂O₃ that is used for aluminum implants. The ion source 108, for example, plays a large role in the ion implantation system 101.

The ion source 108 can use any of the target embodiments disclosed herein. Thus, the ion source 108 can include the components of the ion source 200 or the targets disclosed herein.

In some embodiments, targets disclosed herein which serve as insulators (i.e., an insulator body) may be provided at other locations within the ion implantation system 101. In particular, pairs of insulators may be provided between pairs of electrodes of different potentials along the path of the ion beam 114. For example, these electrodes (and insulators) may be provided between the ion source 108 and the beam-steering apparatus 116, at the end of the beam-steering apparatus 116 proximate the aperture 118, between the aperture 118 and the end station 106, and/or other locations within the ion implantation system 101.

Embodiments of the target body disclosed herein can be formed using machining, chemical etching, and/or additive manufacturing. Additive manufacturing processes are available for many metal-containing materials, including AlN and Al₂O₃. Such additive manufacturing processes may include vat polymerization and binder jet printing. Compared to conventional machining processes, additive manufacturing processes may allow for complex multifaceted thin-walled structures, such as those of the plurality of wave-shaped layers 212. The target 209 may be formed as a unitary structure, or by brazing the plurality of wave-shaped layers 212 to the upper target body 206 and the lower target body 208. It should be understood that certain additive manufacturing processes may use support material between the plurality of wave-shaped layers 212 to support the structure while being formed. Such support material may be removed mechanically or chemically to define the plurality of interstitial gas flow channels 213. Thin walls of the plurality of wave-shaped layers 212 can be used to reduce the amount of material, increase the tracking length, and control heat transfer across the target 209. Each of the plurality of wave-shaped layers 212 can have a thickness defined by multiple layers formed by additive manufacturing. Long tracking lengths provided by the plurality of wave-shaped layers 212 can also increase the life of the target 209.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A target for an ion source comprising:
a target body comprising a plurality of wave-shaped layers sandwiched between an upper target body and a lower target body, wherein adjacent layers of the plurality of wave-shaped layers are offset such that peaks of one layer interface with valleys of an adjoining layer, thereby forming a plurality of interstitial gas flow channels;
wherein the target body defines a central bore along a central axis of the target body that extends between opposite planar ends of the target body, and the plurality of interstitial gas flow channels are open to the central bore.

2. The target of claim 1, wherein the target body includes a metal.

3. The target of claim 2, wherein the target body is one or more of AlN or Al₂O₃.

4. The target of claim 1, wherein each of the plurality of wave-shaped layers has at least two peaks and at least two valleys.

5. The target of claim 1, wherein the target body further comprises a plurality of outer shielding layers disposed between the upper target body and the lower target body and disposed radially outward from the plurality of wave-shaped layers.

6. The target of claim 5, wherein the plurality of outer shielding layers have an aspect ratio (L/w) that is greater than 2:1.

7. The target of claim 5, wherein the target body further comprises a plurality of inner shielding layers disposed between the upper target body and the lower target body and disposed radially inward from the plurality of wave-shaped layers.

8. The target of claim 1, wherein the target body further comprises an interface material disposed between each of the plurality of wave-shaped layers, wherein the interface material joins the peaks and the valleys of the adjacent layers together.

9. The target of claim 1, further comprising:
an arc chamber, wherein the target body is disposed in the arc chamber;
a repeller disposed through the central bore of the target body; and
an indirectly heated cathode disposed in the arc chamber opposite of the repeller.

10. The target of claim 1, wherein the target body is formed by additive manufacturing.

11. The target of claim 10, wherein a thickness of each of the plurality of wave-shaped layers is defined by multiple layers formed by additive manufacturing.

12. The target of claim 1, wherein the target body is formed by brazing the plurality of wave-shaped layers together with the upper target body and the lower target body.

13. The target of claim 1, wherein a height of each of the plurality of wave-shaped layers is less than a wavelength of each of the plurality of wave-shaped layers.

14. A method comprising:
directing a stream of electrons and ions at a repeller and a target body that includes a metal, wherein the target body comprises a plurality of wave-shaped layers sandwiched between an upper target body and a lower target body, adjacent layers of the plurality of wave-shaped layers are offset such that peaks of one layer interface with valleys of an adjoining layer, thereby forming a plurality of interstitial gas flow channels, and the target body defines a central bore along a central axis of the target body that the repeller is disposed within and the plurality of interstitial gas flow channels are open to the central bore; and
eroding metal ions from the target body using the stream of electrons and ions.

15. The method of claim 14, wherein the eroding includes physical sputtering and/or a chemical reaction.

16. The method of claim 14, wherein the target body is one or more of AlN or Al₂O₃.

17. The method of claim 14, further comprising:
feeding an etching gas through the plurality of interstitial gas flow channels, wherein the etching gas reacts with the target body and the stream of electrons and ions to cause the eroding.

18. A method comprising:
forming a target body using additive manufacturing, wherein the target body comprises a plurality of wave-shaped layers sandwiched between an upper target body and a lower target body, and adjacent layers of the plurality of wave-shaped layers are offset such that peaks of one layer interface with valleys of an adjoining layer, thereby forming a plurality of interstitial gas flow channels;
wherein the target body defines a central bore along a central axis of the target body that extends between opposite planar ends of the target body, and the plurality of interstitial gas flow channels are open to the central bore.

19. The method of claim 18, wherein the target body is one or more of AlN or Al₂O₃.

20. The method of claim 18, wherein each of the plurality of wave-shaped layers is defined by multiple layers formed by additive manufacturing.
